(19) United States
(12) Patent Application Publication
(10) Pub. No.: US 2009/0242128 A1
(43) Pub. Date: Oct. 1, 2009

(54) PLASMA PROCESSING APPARATUS AND METHOD

(75) Inventors: Kenji TAGO, Nirasaki City (JP); Hiroshi Tsuchiya, Hwaseong-si (JP); Yuji Otsuka, Nirasaki City (JP); Hiroshi Tsumjimoto, Nirasaki City (JP); Toshifumi Nagaiwa, Nirasaki City (JP); Tsuyoshi Yoshida, Nirasaki City (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/411,814

(22) Filed: Mar. 26, 2009

Related U.S. Application Data
(60) Provisional application No. 61/050,739, filed on May 6, 2008.

(30) Foreign Application Priority Data
Mar. 27, 2008 (JP) 2008-083921

(51) Int. Cl. H01L 21/3065

(52) U.S. Cl. 156/345.28

(57) ABSTRACT

A plasma processing apparatus includes an radio frequency (RF) power supply for applying an RF power for generating a plasma to at least one of an upper and a lower electrode which are disposed to face each other in a processing chamber, a high voltage power supply for applying a high voltage to the lower electrode to electrostatically adsorb the substrate to be held thereon and a control unit for controlling the RF power supply and the high voltage power supply. The control unit controls the high voltage power supply so as to apply a high voltage equal to or less than −1500 V to the lower electrode.

### FIELD OF THE INVENTION

The present invention relates to a plasma processing apparatus and method for performing a plasma etching process or the like on a substrate such as a semiconductor wafer, an LCD substrate or the like.

### BACKGROUND OF THE INVENTION

Conventionally, a plasma processing method for processing a substrate such as a semiconductor wafer, an LCD substrate or the like by using a plasma has been widely employed. For example, in a manufacturing process of semiconductor devices, a plasma etching process for plasma etching, e.g., an oxide film formed on a semiconductor wafer as a target substrate to thereby remove it has been employed as a technique to form a fine electric circuit on the semiconductor wafer.

In a plasma etching apparatus for performing such plasma etching process, the semiconductor wafer is mounted on a top surface of a lower electrode (susceptor) disposed in an airtightly sealed processing chamber. Further, there are known various types of units for generating the plasma inside the processing chamber. In an apparatus for generating a plasma by applying a radio frequency (RF) power to a pair of parallel plate electrodes disposed to face each other vertically, an upper electrode is disposed to face a lower electrode inside the processing chamber. In such configuration, by applying an RF power to at least one of the upper and lower electrodes, the plasma is generated in the processing chamber and etching is carried out.

Meanwhile, the semiconductor wafer mounted on the lower electrode needs to be maintained at a desired temperature during a plasma process. For the purpose, the temperature of the semiconductor wafer is controlled by controlling the temperature of the lower electrode to be maintained at a desired level and bringing the semiconductor wafer into firm contact with the top surface of the lower electrode. Moreover, a thermally conductive gas may be supplied between the top surface of the lower electrode and the rear surface of the substrate to efficiently transfer the heat from the lower electrode to the semiconductor wafer.

Here, a method for electrostatically adsorbing and holding the substrate onto the top surface of the lower electrode by applying an electric power of high voltage thereto is employed to bring the semiconductor wafer into firm contact with the top surface of the lower electrode (see, e.g., Patent Documents 1 to 4). In this case, since the substrate mounted on the top surface of the lower electrode is known to be charged with a negative potential during a plasma process, a positive high voltage is generally applied to the lower electrode to electrostatically adsorb and hold the substrate efficiently. Further, it has been conventionally believed that less particles are adhered to the substrate in case of applying a positive high voltage to the lower electrode, in comparison with a case of applying a negative high voltage thereto.

Alternatively, there can be employed a method for bringing the semiconductor wafer into firm contact with the top surface of the lower electrode by a suction pressure of a pump (see, e.g., Patent Document 5). By allowing the semiconductor wafer to be firmly adhered to the top surface of the lower electrode by means of the suction pump, it is possible to suppress particles from adhering to the substrate which may accompany an electrostatic adsorption. In this case, it has also been proposed to apply a negative voltage of a similar level of potential to that charged to the substrate to the lower electrode during the plasma process in order to further reduce the amount of particles adhering to the substrate.

(Patent Document 1) Japanese Patent Laid-open Application No. 2004-095909

(Patent Document 2) Japanese Patent Laid-open Application No. 2005-236138

(Patent Document 3) Japanese Patent Laid-open Application No. 2006-165093

(Patent Document 4) Japanese Patent Laid-open Application No. 2006-086173

(Patent Document 5) Japanese Patent Laid-open Application No. 2002-100614

In the meanwhile, a semiconductor wafer having a so-called SOI (Silicon on Insulator) structure is being recently manufactured. For MOSFETs on a general integrated circuit, device isolation is achieved by a reverse-biased PN junction. In such a case, however, a stray capacitance is produced between a parasitic diode and a substrate, resulting in a signal delay or a leak current to the substrate. The SOI structure is a structure in which an insulating film is formed under a MOSFET channel to thereby reduce the stray capacitance. By using such SOI structure, high speed and lower power consumption of, for example, a CMOS LSI can be realized. Furthermore, since a separation for device isolation can be made smaller, a distance between, e.g., PMOS-NMOSs can be reduced, so that the arrangement density of devices can be increased.

Since, however, the SOI structure is delicate, the SOI structure formed on the semiconductor wafer may be destroyed due to the influence of the high voltage applied for the purpose of electrostatic adsorption. Meanwhile, the method of adhering the semiconductor wafer to the top surface of the lower electrode by the suction force of the pump also has a drawback in that an additional suction pump is needed to thereby complicate the lower electrode structure even though this method can avoid inflicting any damage in the SOI structure that might be caused by the application of the high voltage.

### SUMMARY OF THE INVENTION

In view of the above, the present invention provides a plasma processing apparatus and method capable of electrostatically adsorbing a substrate without destroying a circuit device such as an SOI structure or the like.

In accordance with an aspect of the present invention, there is provided a plasma processing apparatus including: a processing chamber; a lower electrode disposed in the processing chamber, for mounting a substrate thereon; an upper electrode disposed to face the lower electrode in the processing chamber; a radio frequency (RF) power supply for applying an RF power to at least one of the upper and the lower electrode to generate a plasma; a high voltage power supply for applying a high voltage to the lower electrode to electrostatically adsorb the substrate to be held thereon; and a control unit for controlling the RF power supply and the high voltage power supply, wherein the control unit controls the high voltage power supply so as to apply a high voltage equal to or less than −1500 V to the lower electrode.

In the present application (including specification and claims), the term “high voltage less than or equal to −1500 V” means a negative high voltage, e.g., −2500 V or −3000 V having a magnitude of the high voltage greater than 1500 V. Further, the term “reducing a voltage applied to the lower electrode” implies increasing the magnitude of the negative voltage power (including 0 V), for example, changing the high voltage from 0 V to −1500 V or less. In addition, the term “increasing a voltage applied to the lower electrode” implies decreasing the magnitude of the negative high voltage (including 0 V), for example, changing the high voltage from −1500 V or less to 0 V.

The control unit may control the high voltage power supply such that the high voltage is applied after the RF power is applied to at least one of the upper and the lower electrode by the RF power supply. Further, the control unit may control the RF power supply such that the application of the RF power to at least one of the upper and the lower electrode is finished after the application of the high voltage to the lower electrode is ended.

Furthermore, the control unit may control the high voltage power supply such that the high voltage applied to the lower electrode is lowered stepwise in the beginning of the application of the high voltage to the lower electrode. Moreover, the control unit may control the high voltage power supply such that the high voltage applied to the lower electrode is raised stepwise at the end of the application of the high voltage to the lower electrode.

The substrate mounted on the lower electrode may have an SOI (Silicon on Insulator) structure.

The plasma processing apparatus may further include a temperature control mechanism for controlling the temperature of the lower electrode, wherein the lower electrode is provided with thermally conductive gas supply openings for supplying a thermally conductive gas toward a rear surface of the substrate.

In accordance with another aspect of the present invention, there is provided a plasma processing method for processing a substrate mounted on a top surface of a lower electrode disposed in a processing chamber by applying an RF power to at least one of the lower and an upper electrode facing the lower electrode to generate a plasma, wherein the substrate is adsorbed to be held on the top surface of the lower electrode by a high voltage equal to or less than −1500 V applied to the lower electrode.

The high voltage may be applied after the RF power is applied to at least one of the upper and the lower electrode. Further, the application of the RF power to at least one of the upper and the lower electrode may be finished after the application of the high voltage to the lower electrode is ended.

The high voltage applied to the lower electrode may be lowered stepwise in the beginning of the application of the high voltage to the lower electrode. Further, the high voltage applied to the lower electrode may be raised stepwise at the end of the application of the high voltage to the lower electrode.

A temperature of the lower electrode may be controlled during a plasma process, and a thermally conductive gas may preferably be supplied between the top surface of the lower electrode and a rear surface of the substrate mounted on the lower electrode. Further, more preferably, the thermally conductive gas may be supplied between the top surface of the lower electrode and the rear surface of the substrate mounted on the lower electrode at a pressure equal to or higher than 5 Torr.

In accordance with the present invention, the substrate can be adsorbed to the lower electrode to be held thereon without destroying a circuit device such as an SOI structure by applying a high voltage equal to or less than about −1500 V to the lower electrode.

### BRIEF DESCRIPTION OF THE DRAWINGS

The objects and features of the invention will become apparent from the following description of embodiments given in conjunction with the accompanying drawings, in which:

FIG. 1 presents a schematic view explaining to a plasma processing apparatus in accordance with an embodiment of the present invention;

FIG. 2 sets forth a plane view of a lower electrode;

FIG. 3 provides a timing chart showing a relationship between an application of a radio frequency power and an application of a high voltage;

FIG. 4 sets forth a schematic diagram illustrating erosion of an oxide film formed on the rear surface of a wafer around a thermally conductive gas supply opening;

FIG. 5 depicts a graph showing a relationship between a high voltage applied to the lower electrode and a yield;

FIG. 6 is a graph showing a relationship between a high voltage applied to the lower electrode and an erosion amount of an oxide film on the rear surface of the wafer; and

FIG. 7 offers a graph showing a relationship between a supply pressure of thermally conductive gas and an erosion amount of an oxide film on the rear surface of the wafer.

### DETAILED DESCRIPTION OF THE EMBODIMENTS

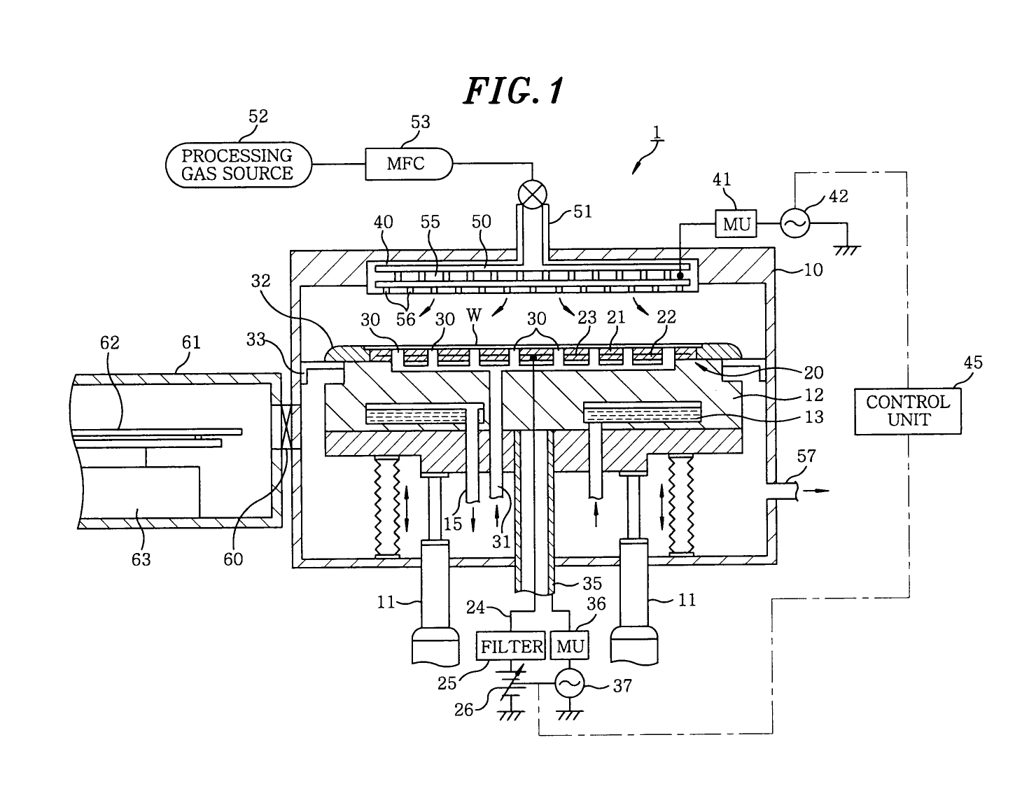

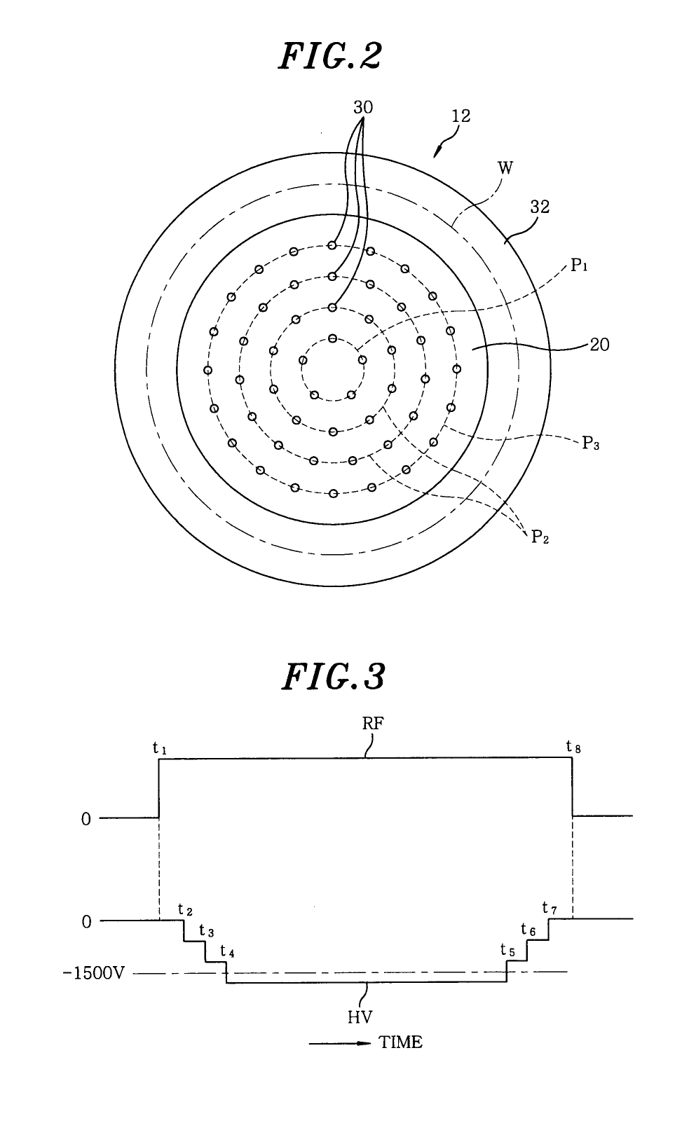

Hereinafter, embodiments of the present invention will be described with reference to the accompanying drawings which form a part hereof. FIG. 1 is a diagram for describing a configuration of a plasma processing apparatus 1 in accordance with a first embodiment of the present invention. FIG. 2 sets forth a plane view of a lower electrode 12 incorporated in the plasma processing apparatus 1. Further, the following description will be provided for the case where the plasma processing apparatus 1 performs a plasma etching process on a semiconductor wafer W serving as a target substrate. In the present specification and drawings, like reference numerals will be given to like parts having like configurations or functions, and redundant description thereof will be omitted.

The plasma processing apparatus 1 includes a processing chamber 10 formed in a cylindrical or rectangular shape made of a conductive material such as aluminum, for example. Disposed inside the processing chamber 10 is a substantially cylindrical lower electrode 12 for mounting the wafer W as the substrate thereon, and the lower electrode 12 is configured to be moved up and down by an elevating mechanism 11 such as a motor. The lower electrode 12 is made of a conductive material such as aluminum or the like. A heat transfer medium circulation path 13 serving as a temperature control mechanism is provided inside the lower electrode 12.

A heat transfer medium whose temperature is appropriately controlled by a temperature control unit (not shown) is introduced into the heat transfer medium circulation path 13 via a heat transfer medium inlet pipe 15. The introduced heat transfer medium circulates in the heat transfer medium circulation path 13, whereby the lower electrode 12 is controlled to be maintained at a desired temperature. Then, the heat of the lower electrode 12 is transferred to the wafer W mounted on a top surface of the lower electrode 12, whereby the wafer W is controlled to be kept at the desired temperature.

Here, a cooling jacket, a heater, or the like can be also used as the temperature control mechanism for controlling the temperature of the lower electrode 12.

The upper portion of the lower electrode 12 is configured as an electrostatic chuck 20 for electrostatically adsorbing and holding the wafer W. The electrostatic chuck 20 is of a circular plate shape having a diameter similar to that of the wafer W. The electrostatic chuck 20 has a configuration in which a conductive film 23 such as a copper foil is disposed between two sheets of films 21 and 22 made of a polymer insulating material such as polyimide resin or the like. The conductive film 23 is connected to a high voltage power supply 26 via a wiring 24 and a filter 25 such as a coil or the like. During a plasma process, a high voltage set as a preset DC voltage is applied from the high voltage power supply 26 while a radio frequency (RF) is cut off by the filter 25. As a result, the wafer W is electrostatically adsorbed to the top surface of the lower electrode (i.e., the top surface of the electrostatic chuck 20) 12 to be held thereon by a Coulomb force generated by the high voltage applied to the conductive film 23.

A number of thermally conductive gas supply openings 30 for supplying a thermally conductive gas toward the rear surface of the wafer W are provided in the top surface of the lower electrode 12. As shown in FIG. 2, the thermally conductive gas supply openings 30 are formed in concentric circles on the top surface of the lower electrode 12. Here, for the convenience of explanation, the thermally conductive gas supply openings 30 are divided into thermally conductive gas supply openings 30 on the innermost side P₁, arranged around the innermost circle; thermally conductive gas supply openings 30 on the outermost side P₃, arranged around the outermost circle; and thermally conductive gas supply openings 30 on intermediate sides P₂, arranged between the innermost side P₁ and the outermost side P₃.

Each thermally conductive gas supply opening 30 is connected with a thermally conductive gas supply pipe 31, and a thermally conductive gas such as helium or the like is supplied from a gas supply source (not shown) into a small space formed between the top surface of the lower electrode 12 and the rear surface of the wafer W with a pressure equal to or higher than, e.g., about 5 Torr. Accordingly, heat can be efficiently transferred from the top surface of the lower electrode 12 toward the wafer W.

An annular focus ring 32 is disposed around the top surface of the lower electrode 12 to surround the periphery of the wafer W mounted on the top surface of the lower electrode 12. The focus ring 32 is made of a conductive or insulating material which does not attract reactive ions, and functions to make the reactive ions effectively directed toward only the wafer W inside the focus ring 32.

Provided between the lower electrode 12 and the inner wall of the processing chamber 10 is a gas exhaust ring 33 having a plurality of baffle holes. A processing gas is uniformly exhausted from the inside of the processing chamber 10 by providing the gas exhaust ring 33.

A power feed rod 35 formed of a conductor in a hollow shape is connected to the bottom surface of the lower electrode 12. The power feed rod 35 is connected to a first radio frequency (RF) power supply 37 via a matching unit (MU) 36 made up of a blocking capacitor or the like. During the plasma process, an RF power of, e.g., about 2 MHz is applied from the first RF power supply 37 to the lower electrode 12.

An upper electrode 40 is disposed above the lower electrode 12. The top surface of the lower electrode 12 and the bottom surface of the upper electrode 40 are disposed to face each other in parallel with a predetermined distance maintained therebetween. The distance between the top surface of the lower electrode 12 and the bottom surface of the upper electrode 40 is adjusted by an elevating mechanism 11.

A second RF power supply 42 is connected to the upper electrode 40 via a matching unit (MU) 41 made up of a blocking capacitor or the like. During the plasma process, an RF power of, e.g., about 60 MHz is applied from the second RF power supply 42 to the upper electrode 40. In such way, by applying the RF powers to the lower electrode 12 and the upper electrode 40 from the first and the second frequency power supply 37 and 42, respectively, a plasma is generated inside the processing chamber 10.

The high voltage power supply 26 for applying the high voltage to the conductive film 23 of the electrostatic chuck 20, the first RF power supply 37 for applying an RF power to the lower electrode 12 and the second RF power supply 42 for applying an RF power to the upper electrode 40 are controlled by a control unit 45. The control operation by the control unit 45 will be explained later in detail.

The upper electrode 40 has a hollow portion 50 therein, and a processing gas supply pipe 51 is connected to the hollow portion 50. The processing gas supplied from a processing gas source 52 is introduced into the hollow portion 50 of the upper electrode 40 via the processing gas supply pipe 51 after its flow rate is controlled by a mass flow controller (MFC) 53. A gas containing, for example, tetrafluoromethane (CF₄), difluoromethane (CH₂F₂), oxygen (O₂) is used as the processing gas.

A baffle plate 55 is installed inside the hollow portion 50 to promote a uniform diffusion of the processing gas. The baffle plate 55 is provided with a number of small holes. Further, a number of processing gas injection openings 56 are provided in the bottom surface of the upper electrode 40 to inject the processing gas from the hollow portion 50 to the inside of the processing chamber 10.

A gas exhaust pipe 57 communicating with a gas exhaust system including a vacuum pump or the like is connected to a lower portion of the processing chamber 10. The inside of the processing chamber 10 is depressurized to a pressure level equal to or less than, e.g., about 100 mTorr through the gas exhaust pipe 57.

A load lock chamber 61 is disposed at a lateral side of the processing chamber 10 via a gate valve 60, and a transfer mechanism 63 having a transfer arm 62 is installed in the load lock chamber 61. After the gate valve 60 is opened, the wafer W is loaded into and unloaded from the processing chamber 10 by the transfer arm 62.

In the plasma processing apparatus 1 having the above-described configuration, the gate valve 60 is opened, and the wafer W to be processed is loaded into the processing chamber 10 by the transfer arm 62 and mounted on the top surface of the lower electrode 12. Thereafter, the transfer arm 62 is retreated from the processing chamber 10 and the gate valve 60 is closed.

Then, in the processing chamber 10, a plasma process on the wafer W mounted on the top surface of the lower electrode 12 is started. During the plasma process, the inside of the processing chamber 10 is depressurized to, e.g., about 100 mTorr through the gas exhaust pipe 57. Further, the processing gas from the processing gas supply source 52 is uniformly supplied into the processing chamber 10 through the processing gas injection openings 56 in the bottom surface of the upper electrode 40.

Then, an RF power of, e.g., about 2 MHz is applied from the first RF power supply 37 to the lower electrode 12, and an RF power of, e.g., about 60 MHz is applied from the second RF power supply 42 to the upper electrode 40. As a result, the processing gas supplied in the processing chamber 10 is turned into a plasma, so that the plasma process is performed on the wafer W.

Further, during the plasma process, a high voltage set as a DC voltage equal to or less than about −1500 V, e.g., −2500 V, −3000 V or the like is applied from the high voltage power supply 26 to the conductive film 23 of the electrostatic chuck 20. The wafer W is electrostatically adsorbed to the top surface of the lower electrode 12 to be held thereon by a Coulomb force generated by the high voltage thus applied to the electrostatic chuck 20.

Here, the application of the high voltage from the high voltage power supply 26 to the lower electrode 12 (i.e., the electrostatic chuck 20), the application of the RF power from the first RF power supply 37 to the lower electrode 12, and the application of the RF power from the second RF power supply 42 to the upper electrode 40 are controlled by the control unit 45 as follows.

As shown in FIG. 3, at time t₁, the RF powers for generating a plasma are applied from the first and the second RF power supply 37 and 42 to the lower electrode 12 and the upper electrode 40, respectively. Then, after the application of such RF powers for plasma generation is begun, the high voltage HV for electrostatic adsorption is started to be applied from the high voltage power supply 26 to the lower electrode 12 at time t₂. When starting the application of the high voltage HV to the lower electrode 12, the high voltage HV is lowered stepwise from, e.g., a DC voltage of 0 V to −1500 V or less in the time sequence of t₂, t₃ and t₄.

Then, a plasma etching process is performed on the wafer W by using the plasma generated in the processing chamber 10. Then, upon the completion of the plasma etching process, the depressurization through the gas exhaust pipe 57 is stopped, and the supply of the processing gas into the processing chamber 10 is also stopped. Further, the application of the RF power to the upper and the lower electrode 40 and 12 is finished, and the application of the high voltage HV to the lower electrode 12 (electrostatic chuck 20) is also stopped.

To elaborate, as illustrated in FIG. 3, for example, the high voltage HV is increased stepwise from the DC voltage equal to or less than about −1500 V to 0 V in the time sequence of t₅, t₆ and t₇. Then, after the application of the high voltage HV to the lower electrode 12 is finished, the application of the RF power to the lower electrode 12 from the first RF power supply 37 and the application of the RF power to the upper electrode 40 from the second RF power supply 42 are also stopped at time t₈.

Then, upon the completion of the plasma process of the wafer W, the gate valve 60 is opened, and the processed wafer W is unloaded from the processing chamber 10 by the transfer arm 62.

With the plasma processing apparatus 1 described above, it is possible to adsorb and hold the wafer W on the lower electrode 12 without destroying devices formed on the wafer W by way of applying the high voltage HV equal to or less than about −1500 V to the lower electrode 12. Therefore, the plasma process can be appropriately performed even on a wafer W having a delicate device such as an SOI structure or the like.

Here, in case that the high voltage HV applied to the lower electrode 12 for the electrostatic adsorption is set to be of a negative value, there is a concern that the adsorption force for the wafer W may be reduced. Therefore, it is desirable that the high voltage HV applied to the lower electrode 12 is in the range, e.g., about from −1500 V to −3000 V.

Further, as described in FIG. 3, since the high voltage HV for the electrostatic adsorption begins to be applied to the lower electrode 12 after the application of the RF powers for the plasma generation is started while the application of the RF powers is ended after the application of the high voltage HV to the lower electrode 12 is stopped, particle adherence to the wafer W that might be caused by the electrostatic adsorption can be suppressed. Furthermore, since the high voltage HV applied to the lower electrode 12 is lowered stepwise down to the DC voltage equal to or less than about −1500 V and then raised stepwise up to 0 V from the DV voltage equal to or less than about −1500V, a damage in the wafer W that might be caused by the electrostatic adsorption can be reduced.

Further, by supplying the thermally conductive gas such as helium toward the rear surface of the wafer W through the thermally conductive gas supply openings 30 provided in the top surface of the lower electrode 12 with a pressure equal to or higher than, e.g., about 5 Torr, heat can be effectively transferred to the wafer W from the top surface of the lower electrode 12, so that the temperature of the wafer W can be controlled with a high precision.

Meanwhile, as illustrated in FIG. 4, an oxide film W′ formed of SiO₂ is formed on the rear surface of the wafer W. This oxide film W′ gets reduced by various kinds of liquid chemical processes performed on the wafer W. Further, since the resistance of the oxide film W′ against the liquid chemical processes is deteriorated due to the influence of the thermally conductive gas supplied between the top surface of the lower electrode 12 and the rear surface of the wafer W, and the oxide film W′ would be especially easily eroded and reduced at its portion 30′ corresponding to the thermally conductive gas supply opening 30. Such deterioration of the oxide film W′ may result in deterioration of electrical characteristics of the wafer W, contamination of the wafer W, and the like.

In the plasma processing apparatus 1 in accordance with the embodiment of the present invention, however, it has been found out that the deterioration of the oxide film W′ on the rear surface of the wafer W due to the influence of the thermally conductive gas can be suppressed by applying the high voltage HV equal to or less than about −1500 V to the lower electrode.

While the invention has been described with respect to the embodiment, it is clear that the above-described embodiment is illustrative in all aspects and do not limit the present invention. It will be understood by those skilled in the art that various changes and modifications may be made without departing form the scope of the invention as defined in the claims. It will also be understood that all such modifications and changes are included in the scope of the present invention.

For example, the above embodiment has been described for the case of applying the RF powers for plasma generation to both of the lower and the upper electrode 12 and 40. However, it may be also possible to apply an RF power for plasma generation to either one of the lower and the upper electrode 12 and 40. Moreover, though the plasma etching apparatus has been described in the present invention, for example, the present invention can also be applied to various kinds of apparatuses for performing a plasma process in a processing chamber, e.g., a plasma CVD apparatus, an ashing apparatus, and the like. Besides, the substrate processed by the plasma processing apparatus of the present invention can be a semiconductor wafer, an organic EL substrate, an FPD (Flat Panel Display) substrate, or the like.

### Example

The present inventors examined a high voltage for electrostatically adsorbing a semiconductor wafer to the top surface of the lower electrode to be held thereon in various aspects. The result is provided below.

First, wafer damages were compared in two cases of electrostatically adsorbing wafers by applying +2500 V and −2500 V to the lower electrode, respectively. As for plasma processing conditions, the internal pressure of the processing chamber was set to be about 30 mTorr, and RF powers to the upper and the lower electrode were set to be about 2000 W and 2500 W, respectively. Further a C₄F₈-based gas was used as a processing gas, and processing time was set to be 10 seconds. Further, antenna ratios of damages to the wafers were set to be 1 M, 100 K and 10 K.

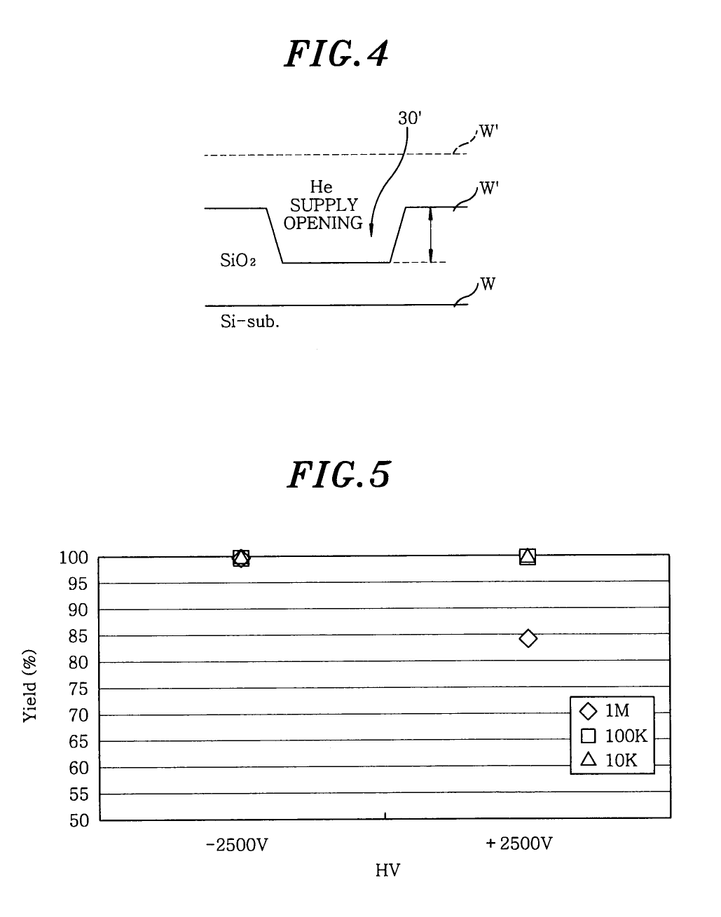

From the result, it has been found that, as illustrated in FIG. 5, when the high voltage HV was set to −2500 V, a damage yield became approximately 100% and substantially no damage was inflicted on the wafer due to the electrostatic adsorption in all of the cases where the antenna ratios were 1 M, 100 K and 10 K. Meanwhile, when the high voltage HV was set to +2500 V, a damage yield became 85% in the case that the antenna ratio was 1 M. Thus, when the electrostatic adsorption is performed with the power of +2500 V, an adverse influence can be caused upon the wafer having a delicate device such as an SOI structure.

Then, the erosion or reduction of an oxide film on portions of wafer's rear surface (30′ in FIG. 4) corresponding to the thermally conductive gas supply openings was examined. First, a plasma process was performed for each of the cases where the electrostatic adsorption of the wafer was performed by applying +2500 V and −2500 V to the lower electrode. As for plasma processing conditions for each wafer, the internal pressure of the processing chamber was set to be about 50 mTorr, and RF power to each of the upper and the lower electrode was set to be about 500 W. Further, a CF₄-based gas was used as a processing gas, and a supply pressure of a thermally conductive gas (He) through the thermally conductive gas supply openings on the innermost side P₁ and the intermediate side P₂ was set to be 10 Torr, and a supply pressure of the thermally conductive gas through the thermally conductive gas supply openings on the outermost side P₃ was set to be 30 Torr. Further, processing time was set to be 60 seconds. After the plasma process, each wafer was processed with 0.5% of chemical liquid for 5 minutes and then rinsed in purified water. Thereafter, erosion or reduction of the oxide film on the portions of the wafer's rear surface corresponding to the thermally conductive gas supply openings was compared.

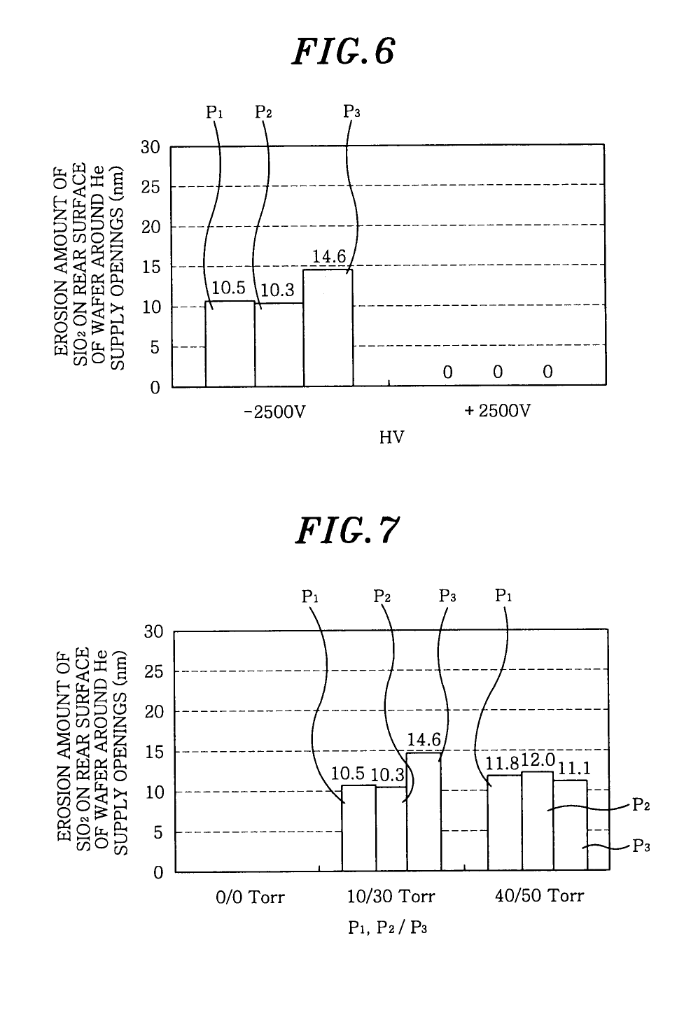

From the result, it has been found that erosion of the oxide film hardly occurred when the high voltage was set to −2500 V, as shown in FIG. 6. Meanwhile, when the high voltage HV was +2500 V, erosion of the oxide film was observed at the portions corresponding to the thermally conductive gas supply openings on all of the innermost side P₁, the intermediate sides P₂ and the outermost side P₃.

Then, a relationship between the supply pressure of the thermally conductive gas and the reduction state of the oxide film on the rear surface of each wafer was studied. First, the wafers were electrostatically adsorbed by applying +2500 V to the lower electrode to be held thereon, and then, a plasma process was conducted. As for plasma processing conditions, the internal pressure of the processing chamber was set to be about 50 mTorr, and RF power to each of the upper and the lower electrode was set to be about 500 W. Further, a CF₄-based gas was used as a processing gas, and processing time was set to be 60 seconds. Further, ratios (P₁, P₂)/P₃ between a supply pressure of a thermally conductive gas (He) through the thermally conductive gas supply openings on the innermost side P₁ and the intermediate side P₂ and a supply pressure of the thermally conductive gas from the thermally conductive gas supply openings on the outermost side P₃ were set to be 0 Torr/0 Torr, 10 Torr/30 Torr and 40 Torr/50 Torr, respectively. For example, in case of 10 Torr/30 Torr, both of the supply pressures for P₁ and P₂ were 10 Torr and that for P₃ was 30 Torr. After the plasma process, each wafer was processed with 0.5% of chemical liquid for 5 minutes and then rinsed in purified water. Thereafter, reduction states of the oxide films on the wafer rear portions corresponding to the thermally conductive gas supply openings were compared.

From the result, it has been found that when the ratio (P₁, P₂)/P₃ became 10 Torr/30 Torr, erosion of the oxide film was observed at the portions corresponding to the thermally conductive gas supply openings on all of the innermost side P₁, the intermediate sides P₂ and the outermost side P₃.

The present invention has many advantages when it is employed in the filed of semiconductor manufacture, for example.

While the invention has been shown and described with respect to the embodiments, it will be understood by those skilled in the art that various changes and modifications may be made without departing from the scope of the invention as defined in the following claims.

What is claimed is:

1. A plasma processing apparatus comprising:
a processing chamber;
a lower electrode disposed in the processing chamber, for mounting a substrate thereon;
an upper electrode disposed to face the lower electrode in the processing chamber;
a radio frequency (RF) power supply for applying an RF power to at least one of the upper and the lower electrode to generate a plasma;
a high voltage power supply for applying a high voltage to the lower electrode to electrostatically adsorb the substrate to be held thereon; and
a control unit for controlling the RF power supply and the high voltage power supply,
wherein the control unit controls the high voltage power supply so as to apply a high voltage equal to or less than −1500 V to the lower electrode.

2. The plasma processing apparatus of claim 1, wherein the control unit controls the high voltage power supply such that the high voltage is applied after the RF power is applied to said at least one of the upper and the lower electrode by the RF power supply.

3. The plasma processing apparatus of claim 1, wherein the control unit controls the RF power supply such that the application of the RF power to said at least one of the upper and the lower electrode is finished after the application of the high voltage to the lower electrode is ended.

4. The plasma processing apparatus of claim 1, wherein the control unit controls the high voltage power supply such that the high voltage applied to the lower electrode is lowered stepwise in the beginning of the application of the high voltage to the lower electrode.

5. The plasma processing apparatus of claim 1, wherein the control unit controls the high voltage power supply such that the high voltage applied to the lower electrode is raised stepwise at the end of the application of the high voltage to the lower electrode.

6. The plasma processing apparatus of claim 1, wherein the substrate mounted on the lower electrode has an SOI (Silicon on Insulator) structure.

7. The plasma processing apparatus of claim 1, further comprising a temperature control mechanism for controlling the temperature of the lower electrode, wherein the lower electrode is provided with thermally conductive gas supply openings for supplying a thermally conductive gas toward a rear surface of the substrate.

8. A plasma processing method for processing a substrate mounted on a top surface of a lower electrode disposed in a processing chamber by applying an RF power to at least one of the lower and an upper electrode facing the lower electrode to generate a plasma,
wherein the substrate is adsorbed to the top surface of the lower electrode to be held thereon by a high voltage equal to or less than −1500 V applied to the lower electrode.

9. The plasma processing method of claim 8, wherein the high voltage is applied after the RF power is applied to said at least one of the upper and the lower electrode.

10. The plasma processing method of claim 8, wherein the application of the RF power to said at least one of the upper and the lower electrode is finished after the application of the high voltage to the lower electrode is ended.

11. The plasma processing method of claim 8, wherein the high voltage applied to the lower electrode is lowered stepwise in the beginning of the application of the high voltage to the lower electrode.

12. The plasma processing method of claim 8, wherein the high voltage applied to the lower electrode is raised stepwise at the end of the application of the high voltage to the lower electrode.

13. The plasma processing method of claim 8, wherein the substrate mounted on the lower electrode has an SOI (Silicon on Insulator) structure.

14. The plasma processing method of claim 8, wherein a temperature of the lower electrode is controlled during a plasma process and a thermally conductive gas is supplied between the top surface of the lower electrode and a rear surface of the substrate mounted on the lower electrode.

15. The plasma processing apparatus of claim 14, wherein the thermally conductive gas is supplied between the top surface of the lower electrode and the rear surface of the substrate mounted on the lower electrode at a pressure equal to or higher than 5 Torr.
